(19) United States
(12) Patent Application Publication
(10) Pub. No.: US 2015/0255302 A1
(43) Pub. Date: Sep. 10, 2015

(54) METHOD OF MANUFACTURING SEMICONDUCTOR DEVICE

(71) Applicant: SAMSUNG ELECTRONICS CO., LTD., SUWON-SI (KR)

(72) Inventors: BYOUNG-MOON YOON, SUWON-SI (KR); YOUNG-OK KIM, SUWON-SI (KR); KYUNG-HYUN KIM, SEOUL (KR); JU-SEON GOO, SEOUL (KR)

(21) Appl. No.: 14/618,024

(22) Filed: Feb. 10, 2015

(30) Foreign Application Priority Data
Mar. 7, 2014 (KR) 10-2014-0027277

(51) Int. Cl. H01L 21/3105; H01L 21/02; H01L 21/324; H01L 21/66

(52) U.S. Cl. CPC H01L 21/31056; H01L 22/12; H01L 21/02271; H01L 21/3247

(57) ABSTRACT

Provided is a method of manufacturing a semiconductor device. The method includes forming an underlying structure on a semiconductor substrate, forming a material layer on the semiconductor substrate having the underlying structure, the material layer including a first region having a first surface disposed at a first height from a surface of the semiconductor substrate and a second region having a second surface disposed at a second height lower than the first height, and planarizing the material layer. The planarization of the material layer includes coating an etchant on the material layer disposed on the semiconductor substrate, and selectively heating the first region of the material layer to increase an etch rate of the first region of the material layer more than an etch rate of the second region of the material layer.

### CROSS-REFERENCE TO RELATED APPLICATION

A claim of priority under 35 U.S.C. §119 is made to Korean Patent Application No. 10-2014-0027277 filed on Mar. 7, 2014, the entire contents of which are hereby incorporated by reference.

### BACKGROUND

Embodiments of the inventive concept relate to a method of manufacturing a semiconductor device, which planarizes a material layer disposed on a semiconductor substrate.

Various structures embodying semiconductor devices are typically formed using photolithography processes. Photolithography processes however may be affected by a surface step difference or thickness dispersion of a material layer to be patterned. In an to minimize surface step difference or the effect of thickness dispersion, chemical-mechanical planarization (CMP) may be performed. However, even though CMP processing may improve surface step difference over a narrow area, its effectiveness is limited when applied to global step difference of wafers.

### SUMMARY

Embodiments of the inventive concept provide a method of manufacturing a semiconductor device which includes forming an underlying structure on a semiconductor substrate, forming a material layer on the semiconductor substrate having the underlying structure, the material layer including a first region having a first surface disposed at a first height from a surface of the semiconductor substrate and a second region having a second surface disposed at a second height lower than the first height, and planarizing the material layer. The planarization of the material layer includes coating an etchant on the material layer disposed on the semiconductor substrate; and selectively heating the first region of the material layer to increase an etch rate of the first region of the material layer more than an etch rate of the second region of the material layer.

In accordance with other embodiments of the inventive concept, a method of manufacturing a semiconductor device includes preparing etch equipment including a heat source supply system and a wet etching system, forming a material layer having a first region and a second region on a semiconductor substrate, and planarizing the material layer using the etching equipment. The planarization of the material layer includes coating a wet etchant on the material layer using the wet etching system, and selectively heating the first region of the material using the heat source supply system to increase an etch rate of the first region more than an etch rate of the second region.

### BRIEF DESCRIPTION OF THE DRAWINGS

The foregoing and other features and advantages of the inventive concepts will be apparent from the following description taken with the accompanying drawings in which like reference characters refer to the same parts throughout the different views. The drawings are not necessarily to scale, emphasis instead being placed upon illustrating the principles of the inventive concepts. In the drawings:

FIG. 1 is a block diagram of semiconductor manufacturing equipment usable in a method of manufacturing a semiconductor device according to embodiments of the inventive concept.

FIG. 2 is a block diagram of a heat source supply system shown in FIG. 1 according to an embodiment of the inventive concept.

FIGS. 3 through 6 are diagrams of a heat source supply system usable in a method of manufacturing a semiconductor device, according to an embodiment of the inventive concept.

FIGS. 7 through 10 are diagrams of a heat source supply system usable in a method of manufacturing a semiconductor device, according to an embodiment of the inventive concept.

FIGS. 11 through 14 are diagrams of a heat source supply system usable in a method of manufacturing a semiconductor device, according to an embodiment of the inventive concept.

FIGS. 15 through 18 are diagrams of a heat source supply system usable in a method of manufacturing a semiconductor device, according to an embodiment of the inventive concept.

FIGS. 19A through 19F are cross-sectional views illustrating a method of manufacturing a semiconductor device according to an embodiment of the inventive concept.

FIG. 20 illustrates a semiconductor substrate on which asymmetric thickness dispersion failures occur.

FIGS. 21A through 21F are cross-sectional views illustrating a method of manufacturing a semiconductor device according to an embodiment of the inventive concept.

### DETAILED DESCRIPTION OF THE EMBODIMENTS

The inventive concept will now be described more fully hereinafter with reference to the accompanying drawings, in which embodiments of the inventive concept are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art.

The terminology used herein is for the purpose of describing particular embodiments only and is not intended to be limiting of the inventive concept. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Terms that describe spatial relationships, such as “beneath,” “below,” “lower,” “above,” “upper,” and the like, may be used herein for ease of description to describe the relationship of one element or feature to another element(s) or feature(s) as illustrated in the figures. It will be understood that such terms are intended to encompass different orientations of the device in use or operation in addition to the orientation(s) depicted in the figures. For example, if the device in the figures is turned over, elements described as “below” or “beneath” other elements or features would then be oriented “above” the other elements or features. Thus, the term “below” can encompass both an orientation of above and below. The orientation of the device may be changed in other ways (e.g., rotated 90 degrees or some other angle) and spatial relationships described herein should be interpreted within the context of the changed orientation.

Embodiments of the inventive concept are described herein with reference to plan and cross-section illustrations that are schematic illustrations of idealized embodiments of the inventive concept. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the inventive concept.

Like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

In the present specification, relative terms, such as “front side” and “back side”, may be used herein for ease of description in describing the inventive concept. Accordingly, a front side or back side does not necessarily indicate a specific direction, location, or component but can be used interchangeably. For example, a front side could be interpreted as a back side, and a back side could be interpreted as a front side. Accordingly, a front side could be termed a first side, and a back side could be termed a second side. Conversely, a back side could be termed a first side, and a front side could be termed a second side. However, to avoid confusion, the terms “front side” and “back side” are not used in the same sense in one embodiment.

In the present specification, a term “near” indicates that any one of at least two components having symmetric concepts is disposed nearer to another specific component than the others thereof. For instance, when a first end is near a first side, it may be inferred that the first end is nearer to the first side than a second end or that the first end is nearer to the first side than a second side.

Hereinafter, a method of manufacturing a semiconductor device according to embodiments of the inventive concept will be described in detail with reference to the accompanying drawings.

To begin, a conceptual block diagram of semiconductor manufacturing equipment 1000 usable in a method of manufacturing a semiconductor device according to embodiments of the inventive concept is illustrated in FIG. 1.

Referring to FIG. 1, the semiconductor manufacturing equipment 1000 usable in the method of manufacturing the semiconductor device according to embodiments of the inventive concept may include a deposition system 100, a thickness measuring system 200, and an etching equipment 300.

The deposition system 100 may be a system configured to deposit various material layers, such as an insulating layer or a conductive layer, on a semiconductor substrate.

The thickness measuring system 200 may be a system configured to measure a thickness or surface step difference of the material layer deposited on the semiconductor substrate using the deposition system 100.

The etching equipment 300 may be a system capable of planarizing a top surface of the material layer deposited on the semiconductor substrate using the deposition system 100. The etching equipment 300 may include a wet etching system 310 and a heat source supply system 320.

The wet etching system 310 may be a system configured to coat the semiconductor substrate with a wet chemical and etch the material layer.

The heat source supply system 320 may be a system configured to locally radiate a heat source only to the corresponding position in which a thickness dispersion failure occurs, out of the entire region of the material layer formed on the semiconductor substrate, and heat the corresponding position. For example, an etch rate may become higher in the region to which the heat source is radiated, than in a region to which the heat source is not radiated. Thus, a surface step difference of the material layer may be reduced in the region to which the heat source is radiated. As a result, a thickness dispersion in the material layer may be improved.

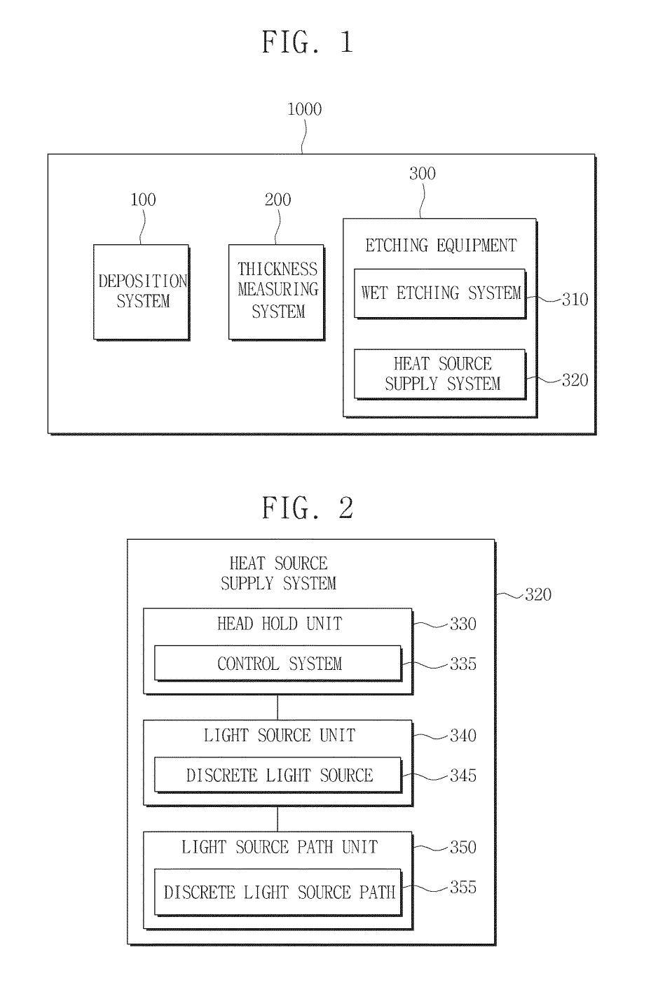

FIG. 2 is a block diagram of the heat source supply system 320 shown in FIG. 1.

Referring to FIGS. 1 and 2, the heat source supply system 320 may include a head hold unit 330, a light source unit 340, and a light source path unit 350.

The head hold unit 330 may include a control system 335 configured to control a light source having an appropriate intensity to be radiated toward the semiconductor substrate, based on data regarding the surface step difference caused by the thickness dispersion failure of the material layer deposited on the semiconductor substrate. The control system 335 may include a central processing unit (CPU).

The light source unit 340 may be connected to the head hold unit 330. The light source unit 340 may serve to locally radiate the light source toward the semiconductor substrate under the control of the control system 335.

The light source unit 340 may include a plurality of discrete light sources 345 having various lattice structures.

The light source unit 340 may include tens to hundreds or more of the discrete light sources 345 according to the area of the semiconductor substrate, which may correspond to a target for a planarization process.

Each of the discrete light sources 345 constituting the light source unit 340 may be a light source capable of transmitting heat, for example, a type of infrared (IR) light.

Each of the discrete light sources 345 may or may not radiate a light source (e.g., on or off) according to a determination by the control system 335 of the head hold unit 330.

The control system 335 of the head hold unit 330 may not only select a discrete light source configured to radiate a light source based on data regarding the thickness dispersion of the material layer to be planarized, but also control the intensity of light radiated by the selected discrete light source and a light radiation time.

The discrete light source 345 may include a plurality of light radiation stages (a stage 1 to a stage N) including an off state in which light is not radiated, according to required light intensity. As the discrete light source 345 passes through the stage 1 to the stage N, the intensity of light radiated to the surface of the semiconductor substrate may be set to become gradually higher. Conversely, as the discrete light source 345 passes through the stage 1 to the stage N, the intensity of light radiated to the surface of the semiconductor substrate may be set to become gradually lower.

The light source path unit 350, which may be a transport path of light radiated from each of the discrete light source 345, may include a plurality of discrete light source paths 355.

The discrete light source path 355 may be formed to be integrally connected with each of the discrete light sources 345.

The light source path unit 350 may be formed to have a predetermined length such that light is radiated by each of the discrete light sources 345 onto the semiconductor substrate as straight as possible. The light source path unit 350 may be formed to a length of about 3 to 5 cm. However, the length of the light source path unit 350 may be changed without limitation depending on process conditions.

Each of the discrete light source paths 355 may be formed of an adiabatic material to prevent transmission of heat between adjacent discrete light source paths 355.

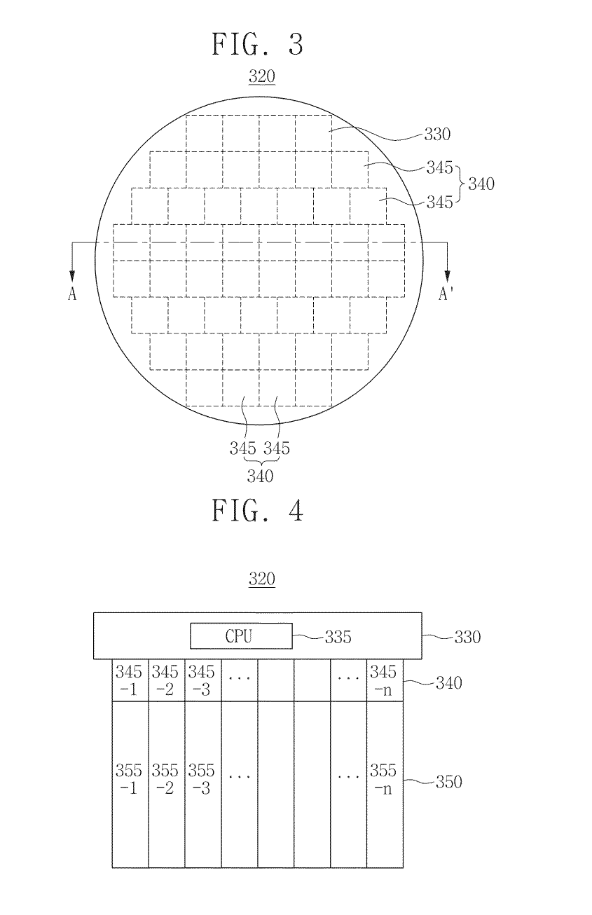

Hereinafter, examples of a heat source supply system usable in a method of manufacturing a semiconductor device, according to various embodiments of the inventive concept, will be described with reference to FIGS. 3 through 18.

A heat source supply system usable in a method of manufacturing a semiconductor device, according to an embodiment of the inventive concept, is illustrated in FIGS. 3 through 6.

FIG. 3 is a top view of the heat source supply system 320.

FIG. 4 is a cross-sectional view of the heat source supply system 320, which is taken along a line A-A′ of FIG. 3.

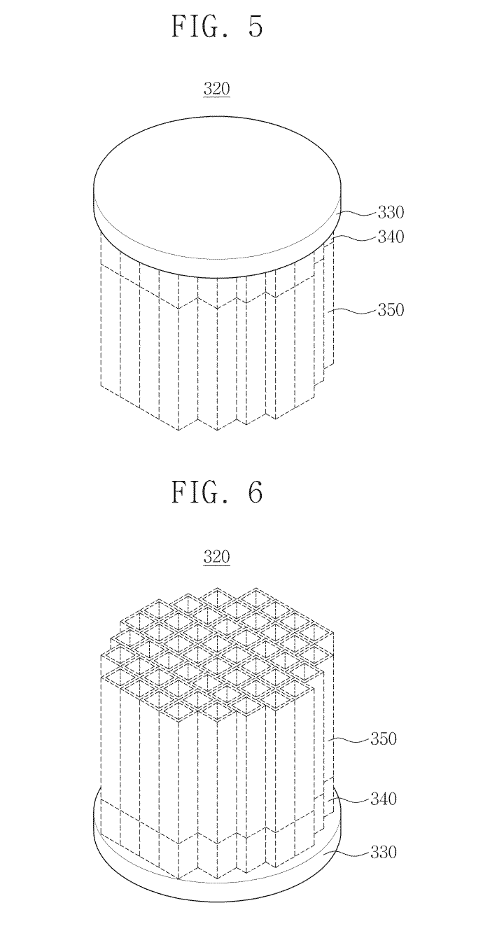

FIGS. 5 and 6 are respectively top and bottom perspective views of the heat source supply system 320.

Referring to FIG. 3, the top view of the heat source supply system 320 may correspond to a top surface of the head hold unit 330 disposed in an uppermost region, out of several elements constituting the heat source supply system 320.

The head hold unit 330 may be formed as a circular shape similar to the shape of a wafer.

A light source unit 340 including a plurality of discrete light sources 345 may be formed under the head hold unit 330.

The discrete light sources 345 constituting the light source unit 340 may have independent tetragonal lattice structures.

The light source unit 340 may include a plurality of discrete light sources 345 to maximize the effects of improvement in the surface step difference of the material layer formed on the semiconductor substrate. The light source unit 340 is not limited to the number of the discrete light sources 345 shown in FIG. 3, but may include tens to hundreds or more of the discrete light sources 345.

The light source unit 340 may be formed to have a larger area than that of the semiconductor substrate so that the entire region of the semiconductor substrate to be planarized can be sufficiently covered with the light source unit 340. Accordingly, the light source unit 340 may be formed such that a discrete light source 345 formed in an outermost corner, out of the discrete light sources 345 formed in the light source unit 340, is disposed at an outer side than an edge region of the semiconductor substrate on a perpendicular line.

FIG. 4 is a cross-sectional view of the heat source supply system 320, which is taken along the direction A-A′ of FIG. 3.

Referring to FIG. 4, the heat source supply system 320 may include a head hold unit 330, a light source unit 340, and a light source path unit 350.

The head hold unit 330 may include a control system 335 (which may include a CPU) configured to control light having an appropriate intensity to be radiated toward the semiconductor substrate, based on data regarding the thickness of the material layer deposited on the semiconductor substrate.

As described with reference to FIG. 3, the light source unit 340 may include a plurality of discrete light source 345-1 to 345-n.

The light source unit 340 may include a plurality of discrete light sources 345-1 to 345-n disposed according to the area of the semiconductor substrate, which may be a target for a planarization process.

Each of the discrete light sources 345-1 to 345-n constituting the light source unit 340 may be a light source capable of transmitting heat, for example, a type of IR light.

Each of the discrete light sources 345-1 to 345-n may or may not radiate light according to a determination by the control system 335 of the head hold unit 330.

The control system 335 of the head hold unit 330 may not only select a discrete light source configured to radiate a light source based on data regarding the thickness dispersion of the material layer to be planarized, but also control the intensity of light radiated by the selected discrete light source and a light radiation time.

Each of the discrete light sources 345-1 to 345-n may include a plurality of light radiation stages (a stage 1 to a stage N) including an off state in which light is not radiated, according to required light intensity. As each of the discrete light sources 345-1 to 345-n passes through the stage 1 to the stage N, the intensity of light radiated to the surface of the semiconductor substrate may be set to become gradually higher. Conversely, as each of the discrete light sources 345-1 to 345-n passes through the stage 1 to the stage N, the intensity of light radiated to the surface of the semiconductor substrate may be set to become gradually lower.

The light source path unit 350, which may be a transport path of light radiated from each of the discrete light sources 345-1 to 345-n, may include a plurality of discrete light source paths 355-1 to 355-n.

The discrete light source paths 355-1 to 355-n may be formed to be integrally connected with the discrete light sources 345-1 to 345-n, respectively.

The light source path unit 350 may be formed as a rectangular pillar shape having a predetermined length such that light is radiated by each of the discrete light sources 345-1 to 345-n onto the semiconductor substrate as straight as possible. The light source path unit 350 may be formed to a length of about 3 to 5 cm. However, the length of the light source path unit 350 may be changed without limitation depending on process conditions.

Each of the discrete light source paths 355-1 to 355-n may be formed of an adiabatic material to prevent transmission of heat between adjacent discrete light source paths 355-1 to 355-n.

Referring to FIGS. 5 and 6, configurations of the head hold unit 330, the light source unit 340, and the light source path unit 350 may be confirmed as in FIG. 4. Also, a plurality of discrete light sources 345 constituting the light source unit 340 and a plurality of discrete light source path units 355 constituting the light source path unit 350 may be confirmed.

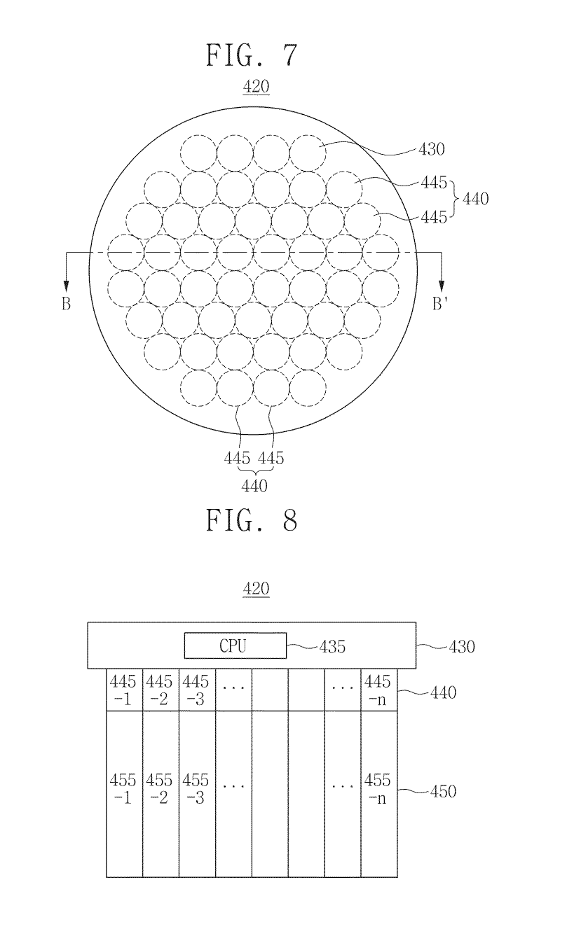

A heat source supply system usable in a method of manufacturing a semiconductor device, according to an embodiment of the inventive concept, is illustrated in FIGS. 7 through 10.

FIG. 7 is a top view of the heat source supply system 420.

FIG. 8 is a cross-sectional view of the heat source supply system 420, which is taken along a direction B-B′ of FIG. 7.

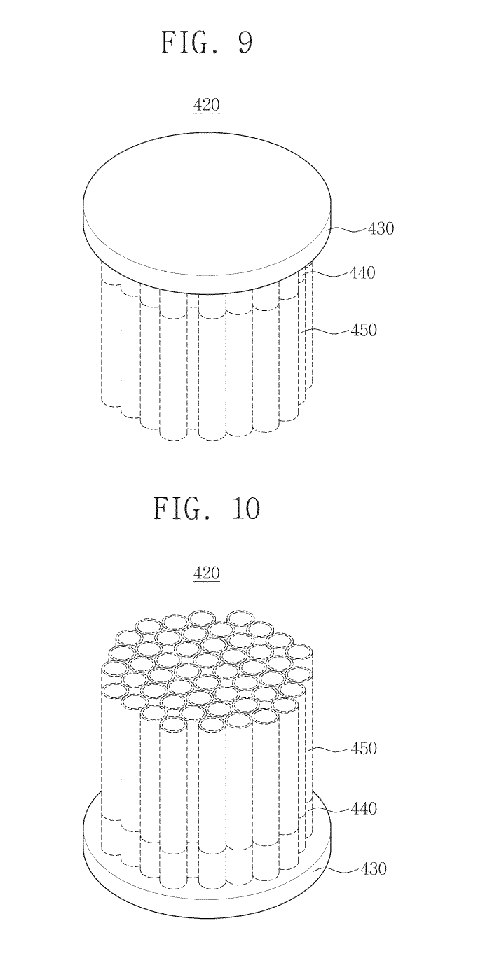

FIGS. 9 and 10 are respectively top and bottom perspective views of the heat source supply system 420.

Referring to FIG. 7, the top view of the heat source supply system 420 may correspond to a top surface of the head hold unit 430 disposed in an uppermost region, out of several elements constituting the heat source supply system 420.

The head hold unit 430 may be formed as a circular shape similar to the shape of a wafer.

A light source unit 440 including a plurality of discrete light sources 445 may be formed under the head hold unit 430.

The discrete light sources 445 constituting the light source unit 440 may have independent circular lattice structures.

The light source unit 440 may include a plurality of discrete light sources 445 to maximize the effects of improvement in the surface step difference of the material layer formed on the semiconductor substrate. The light source unit 440 is not limited to the number of the discrete light sources 445 shown in FIG. 7, but may include tens to hundreds or more of the discrete light sources 445.

The light source unit 440 may be formed to have a larger area than that of the semiconductor substrate so that the entire region of the semiconductor substrate to be planarized can be sufficiently covered with the light source unit 440. Accordingly, the light source unit 440 may be formed such that a discrete light source 445 formed in an outermost corner, out of the discrete light sources 445 formed in the light source unit 440, is disposed at an outer side than an edge region of the semiconductor substrate on a perpendicular line.

FIG. 8 is a cross-sectional view of the heat source supply system 420, which is taken along a direction B-B′ of FIG. 7.

Referring to FIG. 8, the heat source supply system 420 may include a head hold unit 430, a light source unit 440, and a light source path unit 450.

The head hold unit 430 may include a control system 435 configured to control light having an appropriate intensity to be radiated toward the semiconductor substrate, based on data regarding the thickness of the material layer deposited on the semiconductor substrate.

As described with reference to FIG. 7, the light source unit 440 may include a plurality of discrete light sources 445-1 to 445-n.

The light source unit 440 may include a plurality of discrete light sources 445-1 to 445-n disposed according to the area of the semiconductor substrate, which may be a target for a planarization process.

Each of the discrete light sources 445-1 to 445-n constituting the light source unit 440 may be a light source capable of transmitting heat, for example, a type of IR light.

Each of the discrete light sources 445-1 to 445-n may or may not radiate light according to a determination by the control system 435 of the head hold unit 430.

The control system 435 of the head hold unit 430 may not only select a discrete light source configured to radiate light based on data regarding the thickness dispersion of the material layer to be planarized, but also control the intensity of light radiated by the selected discrete light source and a light radiation time.

Each of the discrete light sources 445-1 to 445-n may include a plurality of light radiation stages (a stage 1 to a stage N) including an off state in which light is not radiated, according to required light intensity. As each of the discrete light sources 445-1 to 445-n passes through the stage 1 to the stage N, the intensity of light radiated to the surface of the semiconductor substrate may be set to become gradually higher. Conversely, as each of the discrete light sources 445-1 to 445-n passes through the stage 1 to the stage N, the intensity of light radiated to the surface of the semiconductor substrate may be set to become gradually lower.

The light source path unit 450, which may be a transport path of light radiated from each of the discrete light sources 445-1 to 445-n, may include a plurality of discrete light source paths 455-1 to 455-n.

The discrete light source paths 455-1 to 455-n may be formed to be integrally connected with the discrete light sources 445-1 to 445-n, respectively.

The light source path unit 450 may be formed as a rectangular pillar shape having a predetermined length such that light is radiated by each of the discrete light sources 445-1 to 445-n onto the semiconductor substrate as straight as possible. The light source path unit 450 may be formed to a length of about 3 to 5 cm. However, the length of the light source path unit 450 may be changed without limitation depending on process conditions.

Each of the discrete light source paths 455-1 to 455-n may be formed of an adiabatic material to prevent transmission of heat between adjacent discrete light source paths 455-1 to 455-n.

Referring to FIGS. 9 and 10, configurations of the head hold unit 430, the light source unit 440, and the light source path unit 450 may be confirmed as in FIG. 8. Also, a plurality of discrete light sources 445 constituting the light source unit 440 and a plurality of discrete light source path units 455 constituting the light source path unit 450 may be confirmed.

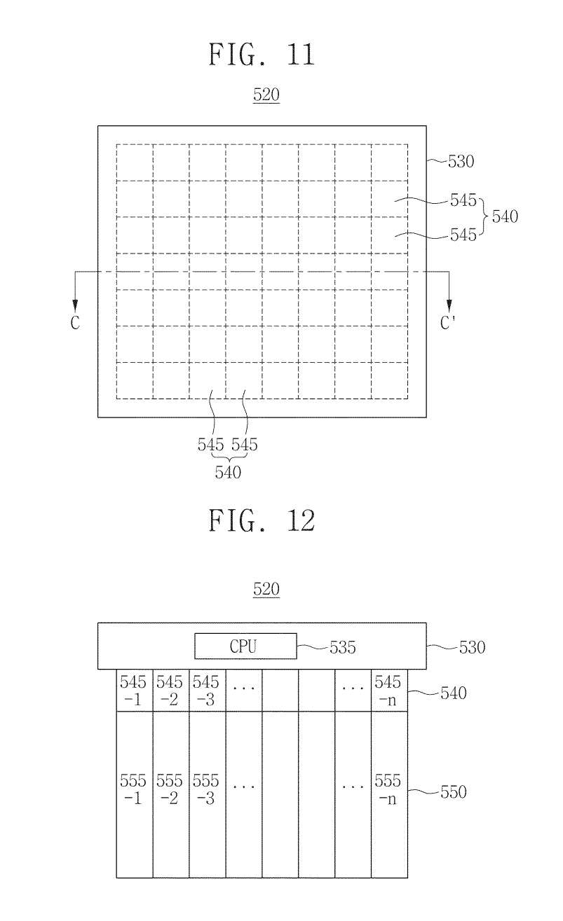

A heat source supply system usable in a method of manufacturing a semiconductor device, according to an embodiment of the inventive concept, is illustrated in FIGS. 11 through 14.

FIG. 11 is a top view of the heat source supply system 520.

FIG. 12 is a cross-sectional view of the heat source supply system 520, which is taken along a direction C-C′ of FIG. 11.

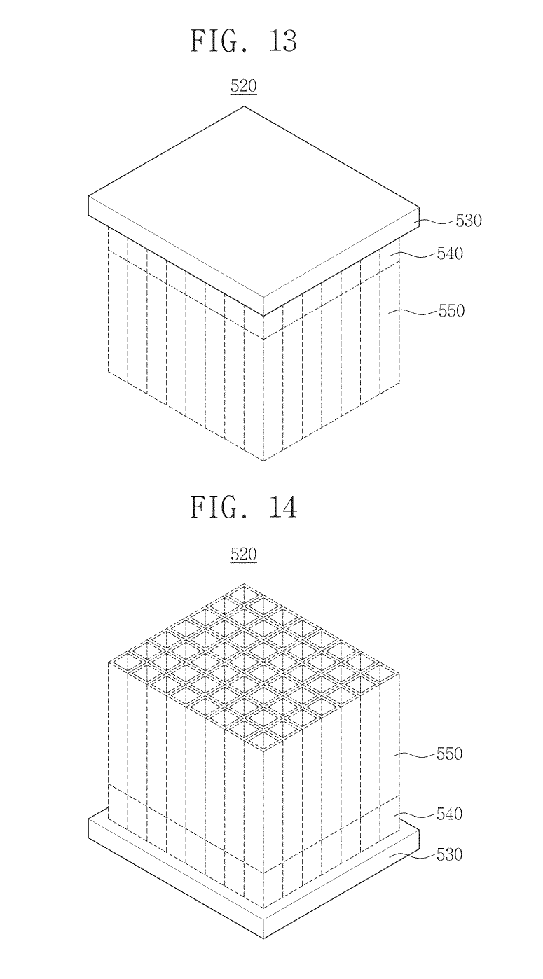

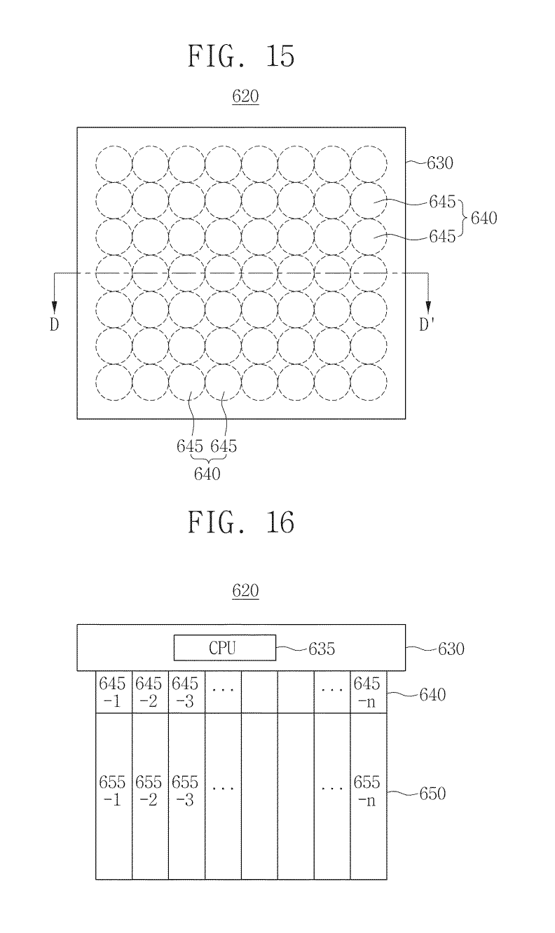

FIGS. 13 and 14 are respectively top and bottom perspective views of the heat source supply system 520.

Referring to FIG. 11, the top view of the heat source supply system 520 may correspond to a top surface of the head hold unit 530 disposed in an uppermost region, out of several elements constituting the heat source supply system 520.

The head hold unit 530 may be formed as a tetragonal shape.

A light source unit 540 including a plurality of discrete light sources 545 may be formed under the head hold unit 530.

The discrete light sources 545 constituting the light source unit 540 may have independent tetragonal lattice structures.

The light source unit 540 may include a plurality of discrete light sources 545 to maximize the effects of improvement in the surface step difference of the material layer formed on the semiconductor substrate. The light source unit 540 is not limited to the number of the discrete light sources 545 shown in FIG. 11, but may include tens to hundreds or more of the discrete light sources 545.

The light source unit 540 may be formed to have a larger area than that of the semiconductor substrate so that the entire region of the semiconductor substrate to be planarized can be sufficiently covered with the light source unit 540. Accordingly, the light source unit 540 may be formed such that a discrete light source 545 formed in an outermost corner, out of the discrete light sources 545 formed in the light source unit 540, is disposed at an outer side than an edge region of the semiconductor substrate on a perpendicular line.

FIG. 12 is a cross-sectional view of the heat source supply system 520, which is taken along a direction C-C′ of FIG. 11.

Referring to FIG. 12, the heat source supply system 520 may include a head hold unit 530, a light source unit 540, and a light source path unit 550.

The head hold unit 530 may include a control system 535 configured to control light having an appropriate intensity to be radiated toward the semiconductor substrate, based on data regarding the thickness of the material layer deposited on the semiconductor substrate.

As described with reference to FIG. 11, the light source unit 540 may include a plurality of discrete light sources 545-1 to 545-n.

The light source unit 540 may include a plurality of discrete light sources 545-1 to 545-n disposed according to the area of the semiconductor substrate, which may be a target for a planarization process.

Each of the discrete light sources 545-1 to 545-n constituting the light source unit 540 may be a light source capable of transmitting heat, for example, a type of IR light.

Each of the discrete light sources 545-1 to 545-n may or may not radiate light according to a determination by the control system 535 of the head hold unit 530.

The control system 535 of the head hold unit 530 may not only select a discrete light source configured to radiate light based on data regarding the thickness dispersion of the material layer to be planarized, but may also control the intensity of light radiated by the selected discrete light source and a light radiation time.

Each of the discrete light sources 545-1 to 545-n may include a plurality of light radiation stages (a stage 1 to a stage N) including an off state in which light is not radiated, according to required light intensity. As each of the discrete light sources 545-1 to 545-n passes through the stage 1 to the stage N, the intensity of light radiated to the surface of the semiconductor substrate may be set to become gradually higher. Conversely, as each of the discrete light sources 545-1 to 545-n passes through the stage 1 to the stage N, the intensity of light radiated to the surface of the semiconductor substrate may be set to become gradually lower.

The light source path unit 550, which may be a transport path of light radiated from each of the discrete light sources 545-1 to 545-n, may include a plurality of discrete light source paths 555-1 to 555-n.

The discrete light source paths 555-1 to 555-n may be formed to be integrally connected with the discrete light sources 545-1 to 545-n, respectively.

The light source path unit 550 may be formed as a rectangular pillar shape having a predetermined length such that light is radiated by each of the discrete light sources 545-1 to 545-n onto the semiconductor substrate as straight as possible. The light source path unit 550 may be formed to a length of about to 5 cm. However, the length of the light source path unit 550 may be changed without limitation depending on process conditions.

Each of the discrete light source paths 555-1 to 555-n may be formed of an adiabatic material to prevent transmission of heat between adjacent discrete light source paths 555-1 to 555-n.

Referring to FIGS. 13 and 14, configurations of the head hold unit 530, the light source unit 540, and the light source path unit 550 may be confirmed as in FIG. 12. Also, a plurality of discrete light sources 545 constituting the light source unit 540 and a plurality of discrete light source path units 555 constituting the light source path unit 550 may be confirmed.

A heat source supply system usable in a method of manufacturing a semiconductor device, according to a fourth embodiment of the inventive concept, is illustrated in FIGS. 15 through 18.

FIG. 15 is a top view of the heat source supply system 620.

FIG. 16 is a cross-sectional view of the heat source supply system 620, which is taken along a direction D-D′ of FIG. 15.

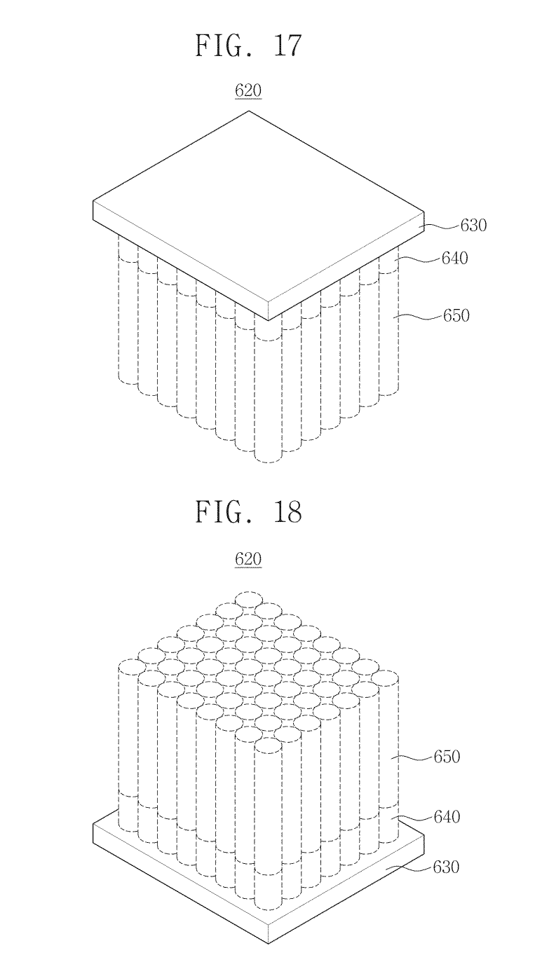

FIGS. 17 and 18 are respectively top and bottom perspective views of the heat source supply system 620.

Referring to FIG. 15, the top view of the heat source supply system 620 may correspond to a top surface of the head hold unit 630 disposed in an uppermost region, out of several elements constituting the heat source supply system 620.

The head hold unit 630 may be formed as a tetragonal shape.

A light source unit 640 including a plurality of discrete light sources 645 may be formed under the head hold unit 630.

The discrete light sources 645 constituting the light source unit 640 may have independent circular lattice structures.

The light source unit 640 may include a plurality of discrete light sources 645 to maximize the effects of improvement in the surface step difference of the material layer formed on the semiconductor substrate. The light source unit 640 is not limited to the number of the discrete light sources 645 shown in FIG. 15, but may include tens to hundreds or more of the discrete light sources 645.

The light source unit 640 may be formed to have a larger area than that of the semiconductor substrate so that the entire region of the semiconductor substrate to be planarized can be sufficiently covered with the light source unit 640. Accordingly, the light source unit 640 may be formed such that a discrete light source 645 formed in an outermost corner, out of the discrete light sources 645 formed in the light source unit 640, is disposed at an outer side than an edge region of the semiconductor substrate on a perpendicular line.

FIG. 16 is a cross-sectional view of the heat source supply system 620, which is taken along a direction D-D′ of FIG. 15.

Referring to FIG. 16, the heat source supply system 620 may include a head hold unit 630, a light source unit 640, and a light source path unit 650.

The head hold unit 630 may include a control system 635 configured to control light having an appropriate intensity to be radiated toward the semiconductor substrate, based on data regarding the thickness of the material layer deposited on the semiconductor substrate.

As described with reference to FIG. 15, the light source unit 640 may include a plurality of discrete light sources 645.

The light source unit 640 may include a plurality of discrete light sources 645-1 to 645-n disposed according to the area of the semiconductor substrate, which may be a target for a planarization process.

Each of the discrete light sources 645-1 to 645-n constituting the light source unit 640 may be a light source capable of transmitting heat, for example, a type of IR light.

Each of the discrete light sources 645-1 to 645-n may or may not radiate light according to a determination by the control system 635 of the head hold unit 630.

The control system 635 of the head hold unit 630 may not only select a discrete light source configured to radiate light based on data regarding the thickness dispersion of the material layer to be planarized, but also control the intensity of light radiated by the selected discrete light source and a light radiation time.

Each of the discrete light sources 645-1 to 645-n may include a plurality of light radiation stages (a stage 1 to a stage N) including an off state in which light is not radiated, according to required light intensity. As each of the discrete light sources 645-1 to 645-n passes through the stage 1 to the stage N, the intensity of light radiated to the surface of the semiconductor substrate may be set to become gradually higher. Conversely, as each of the discrete light sources 645-1 to 645-n passes through the stage 1 to the stage N, the intensity of light radiated to the surface of the semiconductor substrate may be set to become gradually lower.

The light source path unit 650, which may be a transport path of light radiated from each of the discrete light sources 645-1 to 645-n, may include a plurality of discrete light source paths 655-1 to 655-n.

The discrete light source paths 655-1 to 655-n may be formed to be integrally connected with the discrete light sources 645-1 to 645-n, respectively.

The light source path unit 650 may be formed as a rectangular pillar shape having a predetermined length such that light is radiated by each of the discrete light sources 645-1 to 645-n onto the semiconductor substrate as straight as possible. The light source path unit 650 may be formed to a length of about 3 to 5 cm. However, the length of the light source path unit 650 may be changed without limitation depending on process conditions.

Each of the discrete light source paths 655-1 to 655-n may be formed of an adiabatic material to prevent transmission of heat between adjacent discrete light source paths 655-1 to 655-n.

Referring to FIGS. 17 and 18, configurations of the head hold unit 630, the light source unit 640, and the light source path unit 650 may be confirmed as in FIG. 16. Also, a plurality of discrete light sources 645 constituting the light source unit 640 and a plurality of discrete light source path units 655 constituting the light source path unit 650 may be confirmed.

A heat source supply system, which may be applied to improve a surface step difference of a material formed on a semiconductor substrate, may be formed to have not only one of the four shapes shown in FIGS. 2 through 18, but also any other shapes.

A head hold unit disposed in an uppermost end portion of the heat source supply system may be embodied not only as the circular or tetragonal shape described in the embodiments but also as various other shapes, such as an elliptical shape and a triangular shape.

In addition, a lattice structure of a discrete light source constituting a light source unit may be formed not only as the tetragonal or circular shape described in the embodiments but also as various other shapes, such as a triangular shape and a hexagonal shape.

Furthermore, a light source path unit integrally connected with the discrete light source may be formed not only as a tetragonal pillar shape or a cylindrical shape but also as a triangular or hexagonal pillar (honeycomb) shape or various other polygonal pillar shapes, according to the shape of the lattice structure of the discrete light source.

Hereinafter, a method of manufacturing a semiconductor device according to embodiments of the inventive concept using the above-described heat source supply system will be described.

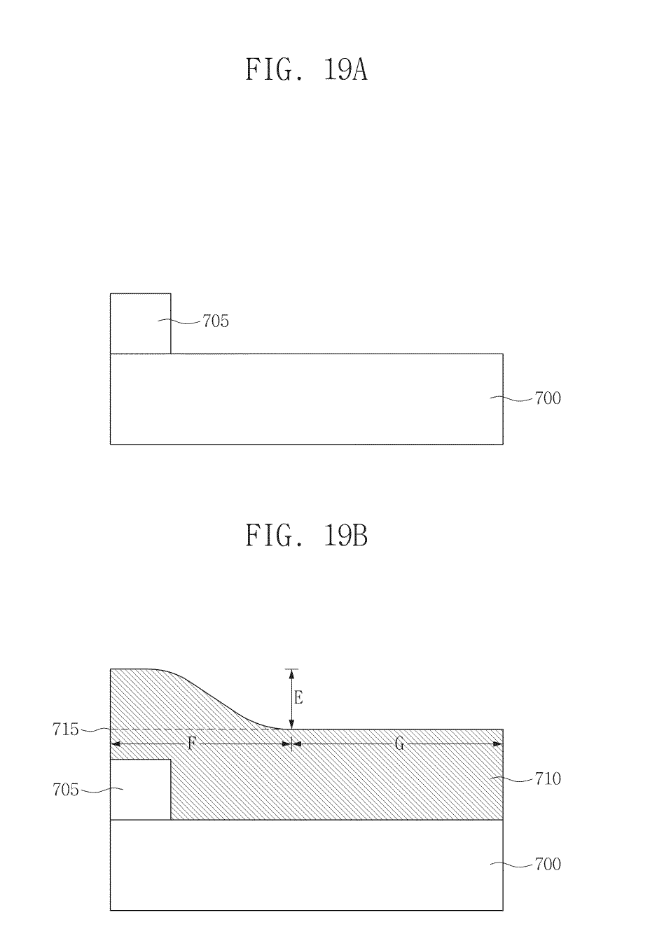

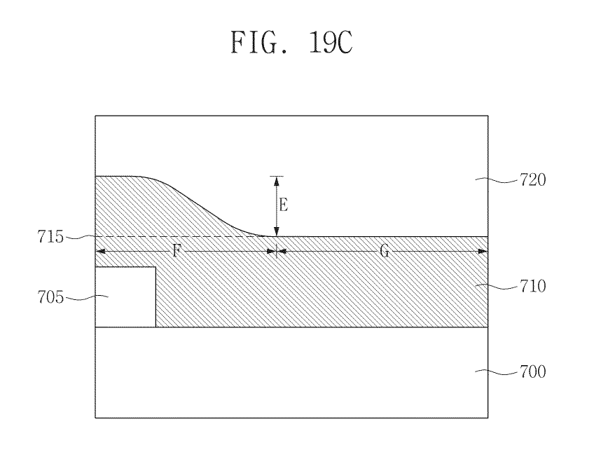

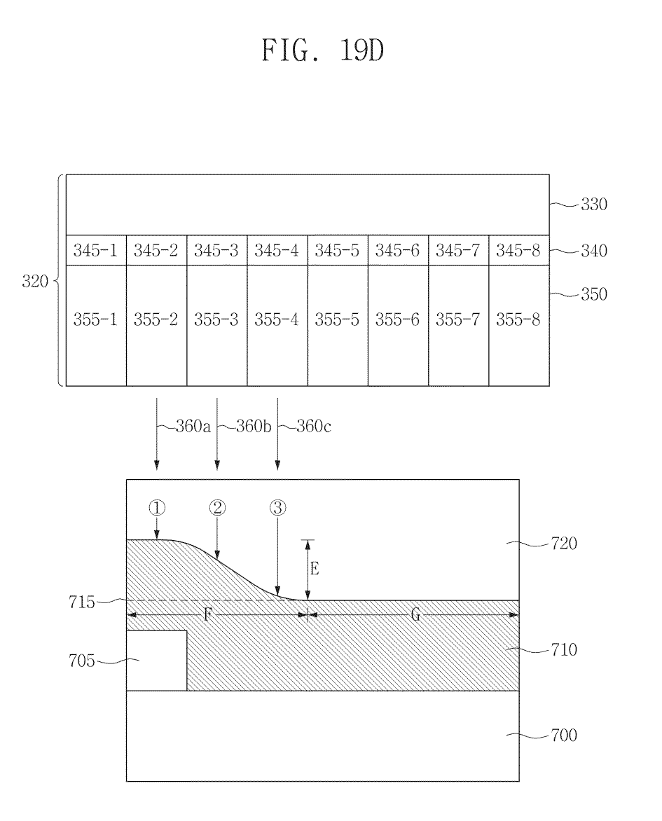

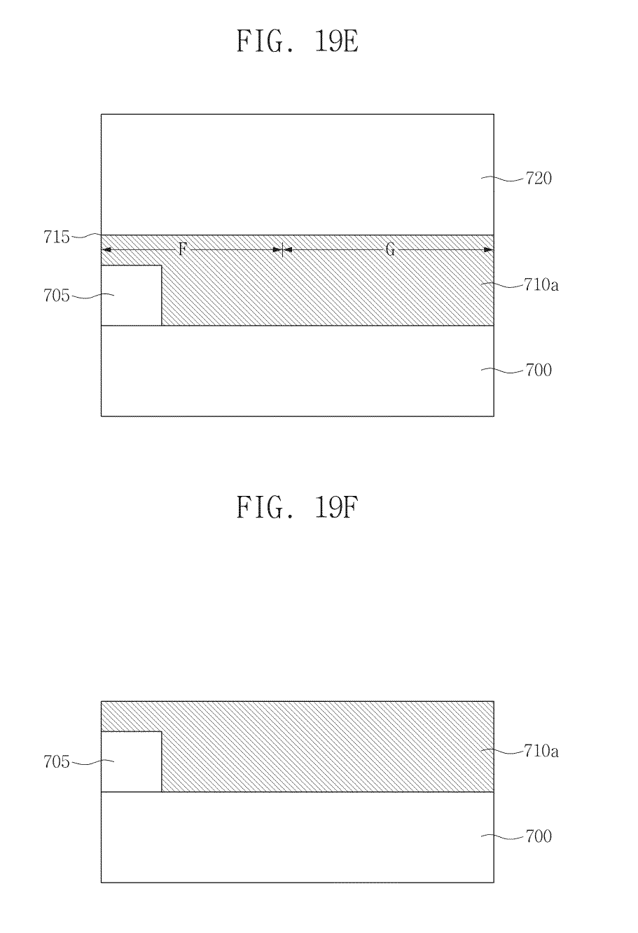

FIGS. 19A through 19F are diagrams illustrating a method of manufacturing a semiconductor device according to embodiments of the inventive concept, which illustrate a process of planarizing an interlayer dielectric (ILD) disposed on a semiconductor substrate.

Referring to FIG. 19A, the method of manufacturing the semiconductor device according to the embodiments of the inventive concept may include forming an underlying structure 705 on a semiconductor substrate (wafer) 700. The underlying structure 705 may include discrete devices of the semiconductor device and data storage elements of a memory device, and/or lines.

Referring to FIG. 19B, a material layer 710 may be formed on the semiconductor substrate 700 having the underlying structure 705.

The formation of the material layer 710 may include employing the deposition system 100 of FIG. 1. For example, the formation of the material layer 710 may include depositing an ILD or an inter-metal dielectric (IMD) using a chemical vapor deposition (CVD) system.

Referring to FIG. 19B, the material layer 710 may include a first region F having a first surface disposed at a first height from a surface of semiconductor substrate 700 and a second region G having a second surface disposed at a second height lower than the first height.

Due to the underlying structure 705, the first region F and the second region G may have top surfaces disposed at different heights. For example, the top surface of the first region F may be formed at a level higher by a first height E than the top surface of the second region G. Accordingly, the material layer 710 may have a surface step difference corresponding to a height difference E between the first and second regions F and G.

Referring to FIG. 19C, a wet chemical 720 may be coated on the material layer 710.

The coating of the wet chemical 720 may include coating the wet chemical 720 on the semiconductor substrate 700 using a single-wafer-type apparatus of guiding and processing wafers one after another.

When the material layer 710 is an oxide-based material layer, the wet chemical 720 may contain chemicals, such as hydrogen fluoride (HF) and buffered oxide etch (BOE).

The wet chemical 720 may be coated to a thickness of about 100 μm. However, since a deposited thickness of the material layer 710 is not standardized, the amount of the wet chemical 720 coated on the material layer 710 may also vary according to the variable deposited thickness of the material layer 710 without specific limitation.

Referring to FIG. 19D, a heat source supply system 320 may be disposed over the semiconductor substrate 700 coated with the wet chemical 720.

The heat source supply system disposed over the semiconductor substrate 700 may be one model selected to meet process conditions, out of four heat source supply systems 320, 420, 520, and 620 described with reference to FIGS. 3 through 18.

After the heat source supply system 320 is disposed over the semiconductor substrate 700, light beams 360a, 360b, and 360c may be locally radiated only to a region in which a surface step difference E has resulted, to planarize the material layer 710.

The light beams 360a, 360b, and 360c may be locally radiated to a region “F” in which the surface step difference E has appeared in the material layer 710, but not radiated to a region “G.”

To locally radiate the light beams 360a, 360b, and 360c only to the region “F”, only discrete light sources 345-2, 345-3, and 345-4 disposed in positions corresponding to the region “F” on a perpendicular line, out of the whole light source unit 340 of the heat source supply system 320 disposed over the semiconductor substrate, may be operated, while the remaining discrete light sources 345-1, 345-5, 345-6, 345-7, and 345-8 may be maintained in an off state.

Meanwhile, on analysis of a distribution state of the material layer 710 in the region “F,” the region “F” may be divided into regions, and according to a thickness which protrudes from a reference surface 715.

The region \textcircled{1} may be a region in which the ILD protrudes to the largest thickness from the reference surface 715. The region \textcircled{2} may have a smaller thickness relative to the region \textcircled{1}, and the region \textcircled{3} may have a smaller thickness than the region \textcircled{2}.

Accordingly, to effectively improve the surface step difference E of the material layer 710, the intensity of each of light beams 360a, 360b, and 360c radiated from each of the discrete light sources 345-2, 345-3, and 345-4 may be differently adjusted according to the thicknesses of the regions \textcircled{1}, \textcircled{2}, and \textcircled{3} in the material layer 710.

Since the material layer 710 is deposited to the largest thickness in excess of the reference surface 715 in the region \textcircled{1}, the largest amount of material layer 710 should be removed. Therefore, the intensity of the light beam 360a radiated from the discrete light source 345-2 may be controlled to be highest.

Since the material layer 710 deposited in excess of the reference surface 715 is relatively thinner in the region \textcircled{2} than in the region \textcircled{1}, the material layer 710 may be removed by a smaller amount than in the region \textcircled{2}. Therefore, the intensity of the light beam 360b radiated from the discrete light source 345-3 may be controlled to be lower than the intensity of the light beam 360a radiated from the discrete light source 345-2.

Since the material layer 710 deposited in excess of the reference surface 715 is relatively thinner in the region \textcircled{3} than in the region \textcircled{2}, the ILD should be removed by a smaller amount than in the region \textcircled{2}. Therefore, the intensity of the light beam 360c radiated from the discrete light source 345-4 may be controlled to be lower than the intensity of the light beam 360b radiated from the discrete light source 345-3.

In an embodiment, the light beams 360a, 360b, and 360c respectively radiated from the discrete light sources 345-2, 345-3, and 345-4 may be controlled to be radiated onto the semiconductor substrate 700 as straight as possible by discrete light source path units 355-2, 355-3, and 355-4 respectively integrally connected with the discrete light sources 345-2, 345-3, and 345-4.

In an embodiment, in the region “F” to which the light beams 360a, 360b, and 360c are locally radiated, a chemical reaction of the wet chemical 720 may occur more energetically than in the region “G” to which light beams are not radiated.

Referring to FIG. 19E, after the light beams are locally radiated to the region “F,” the heat source supply system may be removed from above the semiconductor substrate 700.

Due to the chemical reaction of the wet chemical 720 in the region “F” to which the light beams 360a, 360b, and 360c are locally radiated, an etched amount may be relatively greater in the region “F” than in the region “G” to which light beams are not radiated.

As a result, the ILD in the region “F” in which the surface step difference E was caused, that is, the material layer 710 deposited in excess of the reference surface 715 in the regions \textcircled{1}, \textcircled{2}, and \textcircled{3}, may be removed to planarize the entire surface of the material layer 710a.

Referring to FIG. 19F, the remaining wet chemical may be removed from the oxide layer 710a having the planarized surface using a cleaning solution.

As a result, the ILD 710a in which the surface step difference was improved may exist on the semiconductor substrate 700 from which the wet chemical has been clearly removed.

As described above, light beams may be locally radiated only to a region in which a material layer has been formed at a higher level than in the remaining region, due to an underlying structure, thereby increasing an etch rate in the corresponding region. By performing a partial planarization operation on the region to which light beams have been radiated, the material layer formed on a semiconductor substrate may be planarized.

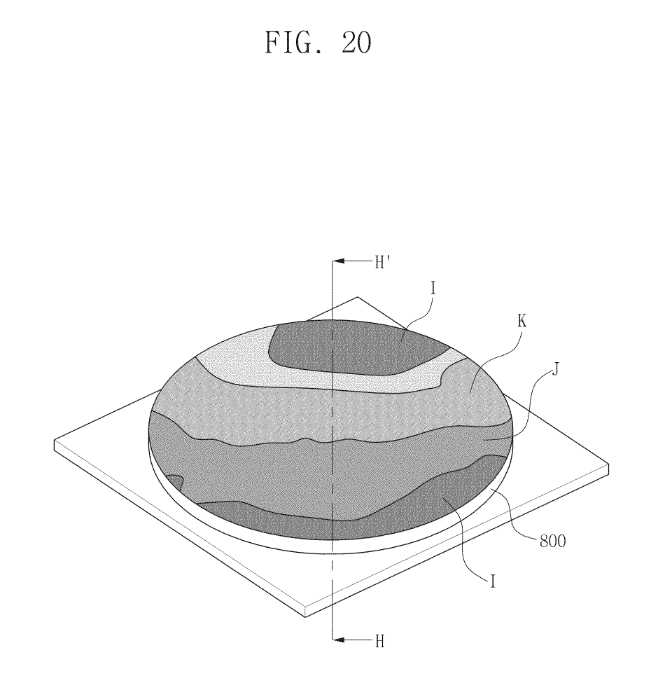

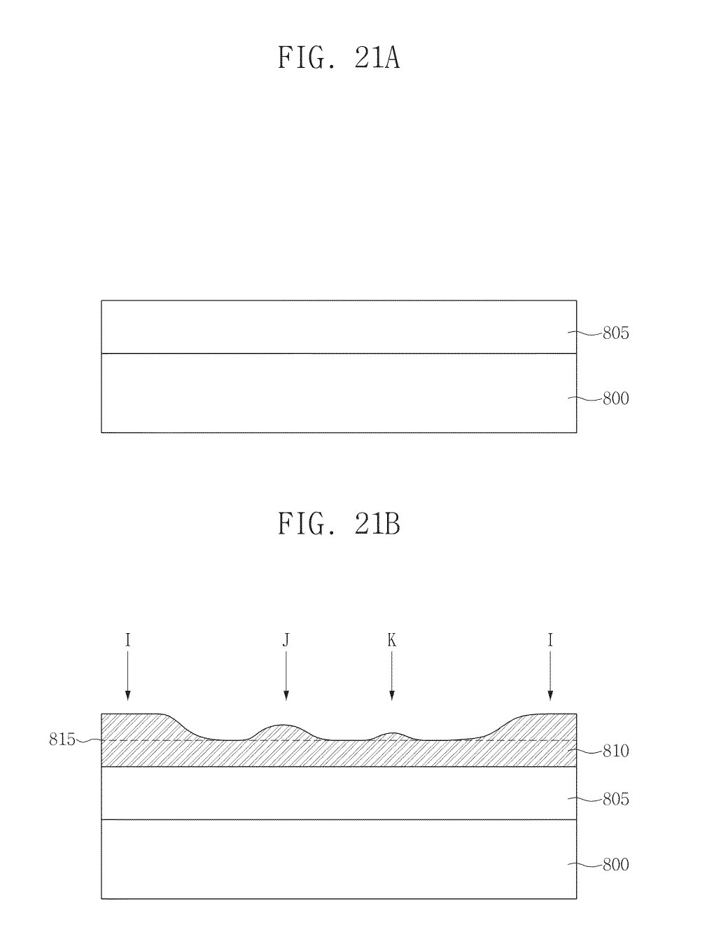

FIG. 20 is a diagram of a semiconductor substrate 800 on which an asymmetrical failure in thickness dispersion occurs.

Referring to FIG. 20, the asymmetrical failure in thickness dispersion has occurred through the entire surface of the semiconductor substrate 800.

In FIG. 20, a darkest region “I” denotes a region in which a material layer is thickest, a region “J” of a brighter color than the region “I” denotes a region in which the material layer is thinner than in the region “I.” Furthermore, a region “K” of a brighter color than the region “J” denotes a region in which the material layer is thinner than in the region “J.”

A failure in the thickness dispersion in the surface of the semiconductor substrate may symmetrically or asymmetrically occur in almost all material layers used in the manufacture of semiconductor devices, such as an oxide layer or nitride layer used as an ILD or IMD, and a polysilicon (poly-Si) layer or metal layer used as a conductive layer.

It may be predicted that the symmetrical or asymmetrical failure in thickness dispersion inevitably occurs due to structural problems (positions of gas spray ports and positions of exhaust ports) of semiconductor manufacturing equipment for depositing a material layer or various problems in process conditions.

When the symmetrical or asymmetrical failure in thickness dispersion is generated to a wafer surface, a pattern failure may occur due to a lack of depth of focus (DOF) margin during photolithography and etching processes.

Accordingly, the failure in thickness dispersion should be eliminated before performing the photolithography and etching processes.

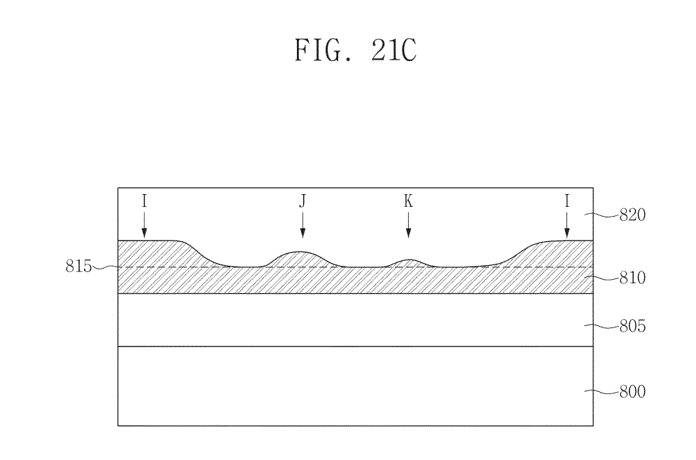

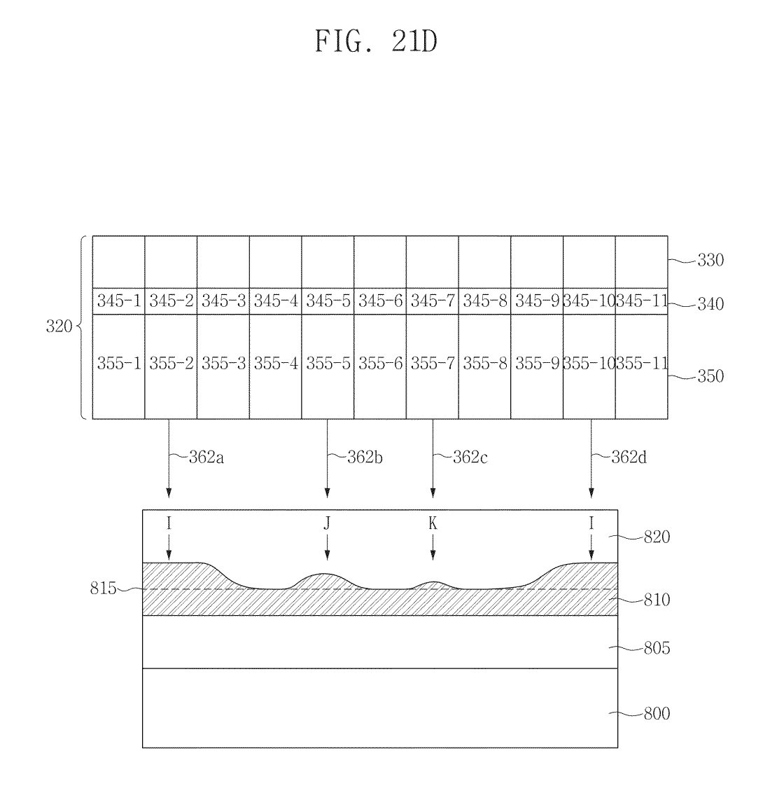

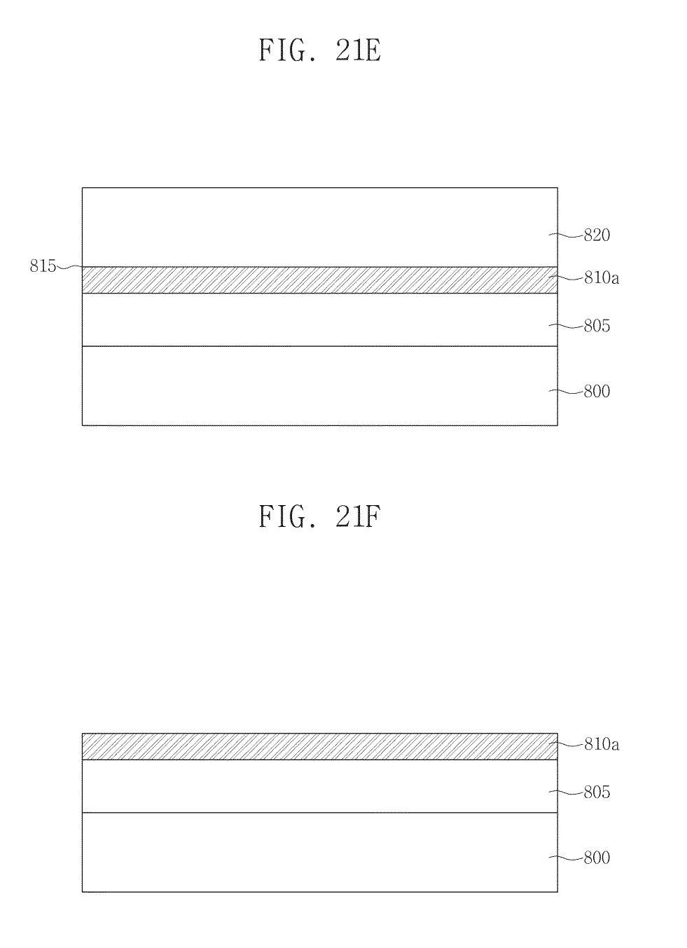

FIGS. 21A through 21E illustrate a method for improving a failure in thickness dispersion along a direction H-H′ of the semiconductor substrate 800 shown in FIG. 20 in a method of manufacturing a semiconductor device according to an embodiment of the inventive concept.

Referring to FIG. 21A, an underlying structure 805 may be formed on the semiconductor substrate 800. The underlying structure 805 may include a gate, a capacitor, or a line.

Referring to FIG. 21B, a material layer 810 may be deposited using a deposition system on the semiconductor substrate 800 on which the underlying structure 805 is formed. The material layer 810 may include an oxide layer, a nitride layer, a poly-Si layer, or a metal layer.

However, as shown in FIG. 21B, the material layer 810 may not be formed to the same thickness on the entire top surface of the semiconductor substrate 800 but protrude from a reference surface 815 in regions “I,” “J,” and “K” to greater thicknesses than in the remaining region.

Due to the regions “I,” “J,” and “K” in which the material layer 810 is formed to greater thicknesses than in the remaining region, an asymmetrical failure in thickness dispersion may occur in the material layer 810.

Thereafter, after forming the material layer 810, the thickness distribution of the entire material layer 810 may be measured.

In this case, the thickness distribution of the material layer 810 may be measured using a thickness measuring apparatus.

A process of measuring the thickness of the material layer 810 using the thickness measuring apparatus may include randomly setting points at which a thickness is to be measured (hereinafter, thickness measurement points). The number of the thickness measurement points may be freely set. For example, 10 to 100 or a smaller or greater number of thickness measurement points may be set.

After the thickness measurement points are set, a length between a top of the material layer 810 to a bottom thereof may be measured. Here, the length between the top of the material layer 810 to the bottom thereof may be a thickness of the material layer 810 at the corresponding measurement point. Furthermore, by measuring the thickness of the material layer 810 at random points through the entire surface of the semiconductor substrate 800 several times, the thickness distribution of the entire material layer 810 formed on the semiconductor substrate 800 may be analyzed.

As a result of the measurement of the thickness distribution of the entire material layer 810, it can be confirmed that the material layer 810 was formed in the regions “I,” “J,” and “K” to greater thicknesses relative to a deposited thickness of the entire material layer 810. In addition, the extent to which the material layer 810 was deposited in excess of the reference surface 815 may be determined in each of the regions “I,” “J,” and “K”.

To improve a thickness dispersion in the material layer 810, an unnecessary portion of the material layer 810 formed in each of the regions “I,” “J,” and “K,” that is, a portion of the material layer 810 deposited in excess of the reference surface 815 as compared with the remaining region, should be removed.

Accordingly, a process of locally removing the material layer 810 excessively deposited in each of the regions “I,” “J,” and “K” may be performed using the heat source supply system 320, 420, 520, or 620.

Referring to FIG. 21C, a wet chemical 820 may be coated on the material layer 810.

The wet chemical 820 may be coated on the semiconductor substrate 800 at an appropriate rpm (revolutions per minute) using a single-wafer-type apparatus of guiding and processing wafers one by one.

In an embodiment, when the material layer 810 is an oxide-based material layer, the wet chemical 820 may contain HF and BOE. When the material layer 810 is a polysilicon (poly-Si)-based material layer, the wet chemical 820 may contain SC1, ammonia, or tetramethylammonium hydroxide (TMAH). When the material layer 810 is a nitride-based material layer, the wet chemical 820 may contain phosphoric acid. When the material layer 810 is a metal-based material layer, the wet chemical 820 may contain a fluorine- or chlorine-based material.

The wet chemical 820 may be coated to a thickness of about 100 μm. However, the thickness of the wet chemical 820 coated on the material layer 810 may be changed according to a deposited thickness of the material layer 810.

Referring to FIG. 21D, a heat source supply system 320 may be disposed over the semiconductor substrate 800 coated with the wet chemical 820.

The heat source supply system disposed over the semiconductor substrate 800 may be applied by selecting a model, which may meet process conditions, from among four heat source supply systems 320, 420, 520, and 620 described with reference to FIGS. 3 through 18.

After the heat source supply system 320 is disposed over the semiconductor substrate 800, light beams 362a, 362b, 362c, and 362d may be locally radiated only to the regions “I”, “J”, and “K” to planarize the material layer 810.

To locally radiate light beams only to the regions “I,” “J,” and “K,” out of the entire light source unit 340 of the heat source supply system 320 disposed over the semiconductor substrate 800, only discrete light sources 345-2, 345-5, 345-7, and 345-10 disposed in positions corresponding to the regions “I,” “J,” and “K” on a perpendicular line may be operated, while the remaining discrete light sources 345-1, 345-3, 345-4, 345-6, 345-8, 345-9, and 345-11 may be maintained in an off state.

Meanwhile, on analysis of a thickness distribution state of the material layer 810, from among the regions “I,” “J,” and “K” deposited in excess of the reference surface 815, the region “I” disposed on left and right sides of the semiconductor substrate 800 may be thickest, the region “J” may be thicker than the region “K” and thinner than the region “I,” and the region “K” may be thinnest. This may mean that the amount of material layer 810 to be removed becomes smaller from the region “I” to the region “K.”

Accordingly, to effectively improve a thickness dispersion in the material layer 810, the intensity of light beams radiated from each of the discrete light sources 345-2, 345-5, 345-7, and 345-10 may be differently adjusted according to the thickness of the material layer 810 in the regions “I,” “J,” and “K” using a control system of a head hold unit.

A largest amount of material layer 810 should be removed from the region “I” because the material layer 810 deposited in excess of the reference surface 815 is thickest in the region “I.” Therefore, the light beams 362a and 362d radiated from the discrete light sources 345-2 and 345-10 may be controlled to have the highest intensity.

Since the material layer 810 deposited in excess of the reference surface 815 is thinner in the region “J” than in the region “I,” the amount of the material layer 810 to be removed may be smaller in the region “J” than in the region “I.” Thus, the intensity of the light beam 362b radiated from the discrete light source 345-5 may be controlled to be lower than the intensity of the light beams 362a and 362d radiated from the discrete light sources 345-2 and 345-10.

Since the material layer 810 deposited in excess of the reference surface 815 is relatively thinner in the region “K” than in the region “J,” the amount of the material layer 810 to be removed may be smaller in the region “K” than in the region “J.” Thus, the intensity of the light beam 362c radiated from the discrete light source 345-7 may be controlled to be lower than the intensity of the light beam 362b radiated from the discrete light source 345-5.

In addition, the light beams 362a, 362b, 362c, and 362d respectively radiated from the discrete light sources 345-2, 345-5, 345-7, and 345-10 may be controlled to be radiated onto the semiconductor substrate 800 as straight as possible by discrete light source path units 355-2, 355-5, 355-7, and 355-10 respectively integrally connected with the discrete light sources 345-2, 345-5, 345-7, and 345-10.

As described above, in the regions “I,” “J,” and “K” to which the light beams 362a, 362b, 362c, and 362d are locally radiated, a chemical reaction of the wet chemical 820 may occur more energetically than in the remaining region to which light beams are not radiated.

Referring to FIG. 21E, after the light beams are locally radiated, the heat source supply system 320 may be removed from above the semiconductor substrate 800.

Due to the energetic chemical reaction of the wet chemical 820 in the regions “I,” “J,” and “K” to which the light beams 362a, 362b, 362c, and 362d are locally radiated, an etched amount may be relatively greater in the regions “I,” “J,” and “K” than in the remaining region to which light beams are not radiated.

As a result, the material layer 810 deposited in excess of the reference surface 815 may be removed from the regions “I,” “J,” and “K” to improve a thickness dispersion in the entire material layer 810a.

Referring to FIG. 21F, the remaining wet chemical may be removed from the material layer 810a of which thickness dispersion was removed using a cleaning solution.

As a result, the material layer 810a of which thickness dispersion was improved may exist on the semiconductor substrate 800 from which the wet chemical has been clearly removed.

As described above, when a failure in thickness dispersion occurs in a material layer formed on a semiconductor substrate, light beams may be locally radiated only to a region in which the failure in thickness dispersion has occurred, thereby increasing an etch rate in the corresponding region to which light beams have been radiated. Thus, by performing a partial planarization operation on the region to which light beams have been radiated, a thickness dispersion in the material layer formed on the semiconductor substrate may be improved.

In accordance with the embodiments of the inventive concept, to planarize the surface of the semiconductor substrate in which a surface step difference or a failure in thickness dispersion has occurred, a wet chemical may be coated on the entire surface of the semiconductor substrate. Thereafter, by increasing the etch rate by locally radiating light beams only to the region in which the surface step difference or failure in thickness dispersion has occurred, the planarization of the surface of the semiconductor substrate may be induced.

When a top surface of a wafer is planarized as described above, a pattern failure caused by a lack of DOF margin may be solved during a photolithography process. As a result, reliability, and productivity of semiconductor devices may be enhanced.

In a method of manufacturing a semiconductor device according to embodiments of the inventive concept, light can be locally radiated only to a region in which a surface step difference or a failure in thickness dispersion has occurred, out of the entire material layer formed on a semiconductor substrate, so that an etch rate can be increased in the region to which light is radiated. Thus, a surface step difference or failure in thickness dispersion of the entire semiconductor substrate can be improved.

By improving the surface step difference or thickness dispersion of the material layer formed on the semiconductor substrate, a pattern failure caused by a lack of depth of focus (DOF) margin can be solved during a photolithography process. As a result, productivity and reliability of semiconductor devices can be enhanced.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures.

What is claimed is:

1. A method of manufacturing a semiconductor device, comprising:
forming an underlying structure on a semiconductor substrate;
forming a material layer on the semiconductor substrate having the underlying structure, the material layer including a first region having a first surface disposed at a first height from a surface of the semiconductor substrate and a second region having a second surface disposed at a second height from the surface of the semiconductor substrate that is lower than the first height; and
planarizing the material layer,
wherein the planarizing of the material layer comprises:
coating an etchant on the material layer disposed on the semiconductor substrate; and
heating the first region of the material layer while not heating the second region of the material.

2. The method of claim 1, wherein the heating of the first region of the material layer comprises employing a heat source supply system including a first light source disposed over the first region of the material layer and a second light source disposed over the second region of the material layer to increase an etch rate of the first region of the material layer more than an etch rate of the second region of the material layer.

3. The method of claim 2, wherein the heating of the first region of the material layer comprises turning off the second light source of the heat source supply system to prevent the heating of the second region of the material layer, and turning on the first light source of the heat source supply system to heat the first region of the material layer using light radiated from the first light source.

4. The method of claim 1, wherein the heating of the first region of the material layer comprises selectively radiating light onto the first region of the material layer,
wherein the light is radiated by varying light intensity according to a thickness of the first region of the material layer.

5. The method of claim 4, wherein the first region of the material layer includes a first height region and a second height region disposed at a lower level than the first height region,
wherein light having a first intensity is radiated to the first height region, and light having a second intensity lower than the first intensity is radiated to the second height region.

6. The method of claim 1, wherein heating the first region of the material layer is performed using a heat source supply system positioned opposite the semiconductor substrate.

7. The method of claim 6, wherein the heat source supply system comprises:
a head hold unit to which data regarding thickness dispersions or surface step differences of the first and second regions of the material layer is input;
a light source unit electrically connected to the head hold unit and including a plurality of discrete light sources; and
a light source path unit integrally connected with the light source unit, the light source path unit through which light radiated from the discrete light sources is transported, the light source path unit including a plurality of discrete light source paths.

8. The method of claim 7, wherein each of the discrete light sources of the heat source supply system includes a type of infrared (IR) light capable of transmitting heat.

9. The method of claim 8, wherein each of the discrete light source paths includes an adiabatic material.

10. The method of claim 1, wherein the formation of the material includes depositing an ILD or an inter-metal dielectric (IMD) using a chemical vapor deposition (CVD) system.

11. The method of claim 1, wherein the etchant comprises at least one of hydrogen fluoride (HF) and buffered oxide etch (BOE).

12. A method of manufacturing a semiconductor device, comprising:
preparing etching equipment including a heat source supply system and a wet etching system;
forming a material layer having a first region and a second region on a semiconductor substrate; and
planarizing the material layer using the etching equipment,
wherein the planarizing of the material layer comprises:
coating a wet etchant on the material layer using the wet etching system; and
heating the first region of the material using the heat source supply system while not heating the second region of the material.

13. The method of claim 12, wherein the heating the first region of the material layer using the heat source supply system comprises:
inputting data regarding thicknesses or surfaces of the first and second regions of the material layer to the heat source supply system, the data being obtained by measuring a thickness dispersion or surface step difference of the material layer using a thickness measuring apparatus; and
operating the heat source supply system using the input data to selectively radiate a heat source to the first region of the material layer.

14. The method of claim 13, wherein the operating of the heat source supply system using the input data to selectively radiate the heat source to the first region of the material layer comprises turning off a second light source of the heat source supply system opposite the second region of the material layer while turning on a first light source of the heat source supply system disposed opposite the first region of the material layer.

15. The method of claim 12, wherein the planarizing of the material layer comprises selectively heating the first region of the material layer on which the wet etchant is coated.

16. The method of claim 12, wherein the planarizing of the material layer comprises employing the heat source supply system including a head hold unit, a light source unit, and a light source path unit,
wherein the employing of the heat source supply system comprises:
inputting data regarding a thickness dispersion of the material layer or data regarding a surface step difference of the material layer to the head hold unit including a control system;
operating a light source unit using the input data by turning on a first light source of the light source unit and turning off a second light source of the light source unit; and
allowing light generated by the first light source to selectively reach the first region of the material layer using the light source path unit.

17. The method of claim 16, wherein the light source unit has a larger area than the semiconductor substrate.

18. A method of manufacturing a semiconductor device, comprising:
forming an underlying structure on a semiconductor substrate;
forming a material layer on the underlying structure and the semiconductor substrate, the material layer having a step structure; and
coating an etchant on the material layer disposed on the semiconductor substrate; and
heating the material layer only at a region where a height of a surface of the material layer from a top surface of the semiconductor substrate has been affected by the underlying structure.

19. The method of claim 18, wherein the formation of the material includes depositing an ILD or an inter-metal dielectric (IMD) using a chemical vapor deposition (CVD) system.

20. The method of claim 18, wherein the etchant comprises at least one of hydrogen fluoride (HF) and buffered oxide etch (BOE).
